(19) United States
(12) Patent Application Publication
(10) Pub. No.: US 2023/0327681 A1
(43) Pub. Date: Oct. 12, 2023

(54) DIGITAL DELTA SIGMA MODULATOR WITH INHERENT SPUR IMMUNITY AFTER NONLINEAR DISTORTION

(71) Applicant: University College Dublin, Dublin 4 (IE)

(72) Inventors: Valerio Mazzaro, Pavia (IT); Michael Peter Kennedy, Dublin (IE)

(21) Appl. No.: 18/131,835

(22) Filed: Apr. 6, 2023

Related U.S. Application Data
(60) Provisional application No. 63/329,678, filed on Apr. 11, 2022.

(51) Int. Cl. H03M 3/00

(52) U.S. Cl. CPC H03M 3/354; H03M 3/424

(57) ABSTRACT

A digital delta-sigma modulator (DDSM) is disclosed with an input signal x[n], an output signal y[n], a quantization error signal e[n] and a dither signal d[n], having an equation described in the z-domain by

Y(z)=STF(z)X(z)+DTF(z)D(z)−NTF(z)E(z)

wherein Y(z), X(z), D(z) and E(z) are z-transforms of the output signal, the input signal, the dither signal, and the quantization error signal, and wherein STF(z), DTF(z) and NTF(z) correspond to a transfer function of the input signal, a transfer function of the dither signal, and a transfer function of the quantization error signal, and wherein the transfer function of the quantization error signal is of the form:

$$NTF ( z ) = {Az}^{- Q} ( 1 + {\sum }_{i = 1}^{K} {c}_{i} {z}^{- i} )$$

where A, Q and K are constants, coefficients cᵢ are real valued and c_{K}≠0 and wherein at least one of the zeroes zⱼ of

$$( 1 + {\sum }_{i = 1}^{K} {c}_{i} {z}^{- i} )$$

satisfies zⱼ≠+1 for j=1, 2, . . . , K

### PRIORITY CLAIM

This application claims priority from and the benefit of U.S. Provisional Patent Application Ser. No. 63/329,678 filed in the U.S. Patent Office on Apr. 11, 2022, the entire content of which is incorporated herein by reference as if fully set forth below in its entirety and for all applicable purposes.

### FIELD OF THE DISCLOSURE

This disclosure relates to digital-to-analog converters based on digital delta sigma modulation. More particularly, this disclosure relates to generating a quantization error that is inherently immune from spurs after distortion by a static nonlinearity.

### DESCRIPTION OF RELATED ART

A digital delta sigma modulator (DDSM) can be used as a controller of a digital-to analog converter (DAC) for implementing the operation of requantization. This involves the reduction of the word length of digital data. It is typically required in order to meet some circuit specification or constraint. The operation of requantization allows one to reduce the number of quantization levels of a digital signal without a significant loss of information. In the process, a quantization error is generated and effectively added to the output signal. If the requantization is not properly implemented, the resulting quantization error can be detrimental for the noise performance of the system.

An example of a system where a DDSM is used as a DAC controller is digital-intensive fractional-N digital phase locked loops (PLLs). In fact, in these systems a digitally controlled oscillator (DCO) is typically used for generating the PLL output signal with a desired frequency, f_{DCO}. In order to select the desired frequency, the DCO is provided with a bank of digitally switched capacitors or resistors that are selected by a tuning word. The values of the capacitors or resistors that are selected determine the frequency of the synthesized signal. Moreover, the smallest capacitance step defines the resolution of the frequency tuning of the DCO which is, in turn, limited by the fabrication technology.

In many cases, the frequency resolution, Δf, provided by the minimum size of the capacitance step is not sufficiently low for a given application. For this reason, dithering of the DCO tuning word is used to improve the time-averaged capacitance resolution. This is typically implemented by a DCO controller that is clocked at a frequency f_{ΔΣ} that is a large fraction of the DCO frequency f_{DCO}. The clock for the divider controller is normally derived from f_{DCO} by frequency division.

The DCO tuning word comprises an integer part, N₀, and a fraction (x/M), where M is called the modulus and x is the primary input signal to the DCO controller. The DCO controller generates an integer valued output, y[n], that, together with N₀, selects the desired value of capacitance. When the first input signal x is constant, the output y[n] may be periodic with a small period. The resulting strongly periodic quantization noise causes spurs at the output of the DCO. Therefore, a second input signal, known as a dither signal d[n], is often applied to the DCO controller to randomize the quantization noise that it produces. FIG. 1 shows a block diagram of a conventional fractional-N PLL with a DCO.

One DCO controller that is commonly used in a fractional-N frequency synthesizer is a Digital Delta-Sigma Modulator (DDSM).

FIG. 2(a) shows a block diagram of a single-quantizer DDSM. The linearized model is given in FIG. 2(b), where the error introduced by the quantizer is denoted by −e[n]. The governing equation of the DDSM in the z domain is

Y(z)=STF(z)X(z)+DTF(z)D(z)−NTF(z)E(z),

where Y(z), X(z), D(z), and E(z) are the z-transforms of the output, primary input, dither signal and quantization error signals y[n], x[n], d[n] and e[n], respectively. Moreover, STF(z), DTF(z) and NTF(z) are the transfer functions from the primary input, dither input and quantization error to the output. According to the block diagram of FIG. 2(a), these transfer functions are equal to

$$STF ( z ) = \frac{F ( z )}{1 + F ( z ) G ( z )} ,$$

$$DTF ( z ) = \frac{V ( z ) F ( z )}{1 + F ( z ) G ( z )} ,$$

$$NTF ( z ) = \frac{1}{1 + F ( z ) G ( z )} .$$

The single-quantizer DDSM architecture requires a multibit quantizer and can suffer from stability problems due to delays in the transfer functions F(z) and G(z) in FIG. 2.

An alternative implementation of the same governing equation that requires simpler quantizers and has a feedforward structure is the MultistAge noise SHaping (MASH) digital delta-sigma modulator. FIG. 3 shows a block diagram of a multi-quantizer MASH DDSM that comprises a cascade of L number error feedback modulator (EFM) stages (denoted EFMⱼ, j=1, 2, . . . , L in FIG. 3) and an error cancellation network. Each EFM stage has an input xⱼ, a first output yⱼ and a second output eⱼ, which is called the error, as shown in FIG. 4(a). The first output yⱼ of each error feedback modulator stage in FIG. 3 is combined in the error cancellation network. In the case of all but the L-th stage, the second output eⱼ is passed to the input of the next error feedback modulator stage in the cascade.

For the sake of completeness, FIG. 4(b) shows an implementation of an EFM. The governing equation in the z domain is

Y(z)=Az^{-Q}X(z)−Az^{-Q}(1−H(z))E(z),

where A and Q are constants. According to the equation above, one can deduce that the signal and noise transfer functions are equal to

STF(z)=Az^{-Q},

NTF(z)=Az^{-Q}(1−H(z)).

FIG. 5 shows a block diagram of a multi-level multi-quantizer nested cascaded MASH DDSM that comprises T levels of L cascaded error feedback modulator stages (denoted EFM_{i,j}, i=1, 2, . . . , T and j=1, 2, . . . , L in FIG. 5) and an error cancellation network. The sum of x[n] and the filtered dither, denoted \hat{x}[n], is split into components \hat{x}ᵢ[n], with i=1, 2, . . . , T, wherein

$${\hat{x}}_{i} [ n ] = \{ \begin{matrix}⌊ \frac{\hat{x} [ n ]}{{\prod }_{k = i + 1}^{T} {M}_{k}} ⌋ - {M}_{i} ⌊ \frac{\hat{x} [ n ]}{{\prod }_{k = i}^{T} {M}_{k}} ⌋ & if \hat{x} [ n ] \geq 0 \\ ⌈ \frac{\hat{x} [ n ]}{{\prod }_{k = i + 1}^{T} {M}_{k}} ⌉ - {M}_{i} ⌈ \frac{\hat{x} [ n ]}{{\prod }_{k = i}^{T} {M}_{k}} ⌉ & if \hat{x} [ n ] < 0\end{matrix}$$

where the symbols └⋅┘ and ┌⋅┐ denote, respectively, the floor and ceiling functions. Moreover, Mᵢ is the modulus of every EFM of the i-th level and M=Πᵢ₌₁^{T}Mᵢ. Each EFM_{i,j} with i=1, 2, . . . , (T−1) and j=2, . . . , L has the sum (e_{i,(j-1)}[n]+y_{(i+1),j}[n]) as input.

In the case of all the stages of the T-th level, except for EFM_{T,1}, the input to the EFM is provided by the second output e_{T,(j-1)} passed by the previous error feedback modulator stage in the cascade. In the case of EFM_{T,1}, the EFM is fed directly by \hat{x}_{T}[n]. Lastly, each first stage of every level but the last (EFM_{i,1} with i=1, 2, . . . , (T−1)), has the sum \hat{x}ᵢ[n]+y_{(i+1),i}[n] as input. Then, the primary outputs of all the stages of the first level (y_{1,j} with j=1, 2, . . . , L) are combined in the error cancellation network.

The DCO controller implemented with a DDSM generates an error when it approximates the fractional value x/M with its integer output y[n]. This modulation error translates into an error of the instantaneous frequency synthesized by the DCO. The integration of this error contributes to the resulting DCO phase noise. In order not to degrade the phase noise performance of the DCO (and consequently the synthesizer), the modulation error is desired to have a spur-free and high-pass shaped power spectral density (PSD). This can be achieved by properly designing the noise transfer function of the DDSM.

Spurs can be experienced in the spectrum of the modulation error because of cycles established in the operation of the modulator. These are known to occur when the first input is constant.

As previously noted, one known technique for breaking the periodicity of the output of a DDSM-based DCO controller is to introduce the additive random or pseudorandom dither signal d[n] at the input of the DDSM. This dither signal can be spectrally masked at the output of the DDSM by shaping it using a filter that has a transfer function V(z), as illustrated in FIG. 3.

A typical second-order MASH 1-1 digital delta-sigma modulator with unfiltered dither is illustrated in FIG. 6. The cascade comprises two first-order error feedback modulators (denoted EFMⱼ with j=1, 2.) and an error cancellation network. The pseudorandom binary dither signal d[n] with a transfer function V(z)=1 is added to the input of the first stage.

In the z domain,

$$Y ( z ) = STF ( z ) X ( z ) + DTF ( z ) D ( z ) - NTF ( z ) {E}_{2} ( z ) ,$$

$$where STF ( z ) = \frac{1}{M} , DTF ( z ) = \frac{1}{M} , NTF ( z ) = \frac{1}{M} {( 1 - {z}^{- 1} )}^{2} .$$

and Y(z), X(z), D(z) and E₂(z) are the Z-transforms of y, x, the dither signal d, and the quantization error e₂[n] of the second EFM stage in FIG. 6. In particular, the power spectral densities (PSDs) of NTF(z) E₂(z) and DTF(z) D(z) are shown in FIG. 7.

The signal y[n] contains a first component that is related to the input signal x[n], a second component due to the dither signal d[n], and a third component that is due to the quantization error signal e₂[n]. The signal y[n] can select the tuning capacitance of the DCO by switching capacitors in a capacitor bank or using a resistive digital to analog converter (DAC) to tune a voltage-dependent capacitor. Because of mismatches between the capacitances of the capacitors in the capacitor bank or the resistors in the DAC, the signal y[n] encounters a static nonlinearity, [symbol] [⋅], that distorts it into y^{NL}[n]. Interaction with the nonlinearity causes the level of the noise floor to increase due to noise folding. In addition, a set of spurious tones is generated. This is shown schematically in FIG. 8.

Furthermore, the scaled accumulation of the distorted signal y^{NL}[n] contributes a component of phase noise to the DCO which is due to the modulation, denoted φ_{DCO,ΔΣ}^{NL}[n] in FIG. 8. This phase noise introduces additional noise into the synthesizer loop which is exacerbated by the presence of the nonlinearity.

FIG. 9 compares the power spectral densities of the output of the DCO controller y[n] and the distorted output y^{NL}[n]. The DCO controller has been implemented with a conventional MASH 1-1 with unfiltered LSB dither added to the first EFM stage, as shown in FIG. 6. The fractional value approximated by y[n] is x/M=½⁸. The nonlinearity is

[symbol]

[x]=0.025+0.933x−0.0875x²+0.0542x³.

FIG. 9 shows that the effects of the nonlinearity are (i) an increased noise floor due to noise folding and (ii) the generation of periodic noise components that manifest in the spectrum as spurious tones. Despite the dither, which has made the spectrum of y[n] spur-free, the spectrum of y^{NL}[n] exhibits periodic tones at normalized frequency 5.86×10⁻³ and its harmonics.

FIG. 10 shows a block diagram of one known architecture for reducing fractional spurs in a synthesizer with a DDSM-based DCO controller in the presence of a memoryless polynomial nonlinearity. Compared to the structure in FIG. 8, a decoder with bit-rotation is used to randomize the effect of the nonlinearity. The spectrum of the resulting distorted signal, denoted ŷ^{NL}[n], is spur-free. However, the spectrum has a higher folded noise floor.

FIG. 11 shows the simulated power spectral density of the distorted output of a DCO controller composed of a MASH 1-1 with unfiltered LSB dither in the cases where (a) there is a decoding with bit rotation of the DDSM output y[n] and (b) there is no decoding with bit rotation of the DDSM output y[n]. The fractional value is set to x/M=½⁸, as in the cases simulated in FIG. 9. The results shown in FIG. 11 confirm that the use of bit-rotation successfully mitigates the fractional spurs that are induced by the nonlinearity. However, it can be seen that the randomization caused by the bit rotation introduces a higher low-frequency folded noise floor. The level of folded noise is 15 dB higher than in the case where bit rotation is not applied.

Furthermore, compared to the DCO controller shown in FIG. 8, additional hardware is required to implement the bit rotation architecture of FIG. 10.

It will be appreciated that fractional spurs and noise degrade the performance of the overall system in which the synthesizer is being used. This has been found to have a detrimental effect when the system is being used in applications such as communications, radar, and instrumentation.

While this example represents a case where the DDSM receives a constant input, a digital delta sigma modulator can be used as a DAC controller in the more generic case where the input is time-varying, such as in the case of audio/video processing blocks. Also in these applications, the presence of nonlinearity may degrade the noise performance with the introduction of spurs and folded noise.

Accordingly, it would be advantageous to be able to mitigate nonlinearity-induced spurs in the presence of nonlinearities without introducing excessive additional folded noise.

### SUMMARY OF THE EMBODIMENTS

Various embodiments of a DAC controller, denoted INIS-DDSM, for mitigating nonlinearity-induced spurs and noise are disclosed.

Broadly speaking, a digital delta-sigma modulator (DDSM) is disclosed with an input signal x[n], an output signal y[n], a quantization error signal e[n] and a dither signal d[n], having an equation described in the z-domain by

Y(z)=STF(z)X(z)+DTF(z)D(z)−NTF(z)E(z)

wherein Y(z), X(z),D(z) and E(z) are z-transforms of the output signal, the input signal, the dither signal, and the quantization error signal, and wherein STF(z), DTF(z) and NTF(z) correspond to a transfer function of the input signal, a transfer function of the dither signal, and a transfer function of the quantization error signal, and wherein the transfer function of the quantization error signal is of the form:

$$NTF ( z ) = {Az}^{- Q} ( 1 + {\sum }_{i = 1}^{K} {c}_{i} {z}^{- i} )$$

where A, Q and K are constants, coefficients cᵢ are real valued and c_{K}≠0, and wherein at least one of the zeroes zⱼ of

$$( 1 + {\sum }_{i = 1}^{K} {c}_{i} {z}^{- i} )$$

satisfies zⱼ≠+1 for j=1, 2, . . . , K.

In one embodiment, the coefficients cᵢ are equal to −1, 0 or 1.

In one embodiment, the coefficients cᵢ are valued such that the noise transfer function can be represented in the form:

$$NTF ( z ) = {Az}^{- Q} ( 1 - {z}^{- 1} ) ( 1 + {\sum }_{i = 1}^{K - 1} {d}_{i} {z}^{- i} )$$

and wherein

$${\sum }_{i = 1}^{K} \vert {c}_{i} \vert \leq - 1 + 2 {\sum }_{i = 1}^{K - 1} \vert {d}_{i} \vert$$

In one embodiment, the R coefficients cᵢ are equal to −1, (R−1) of the coefficients cᵢ are equal to +1 and the other (K−2R+1) of the coefficients cᵢ are equal to zero, with

$$R \leq \frac{K + 1}{2} .$$

In one embodiment, the z-domain equation is implemented with a multi-bit single-quantizer DDSM architecture.

In one embodiment, the z-domain equation is implemented with a multistage noise shaping cascaded DDSM architecture comprising an error cancellation network and L≥2 error feedback modulator (EFM) stages, wherein an error output eⱼ of stage j is applied as an input to stage (j+1) and wherein outputs yⱼ of the L stages are combined in the error cancellation network to provide the output y.

In one embodiment, wherein the Error Feedback Modulator (EFM) stages comprise a first portion and a second portion, wherein the first portion comprises (L−1) error feedback modulator stages and the second portion comprises the Lth error feedback modulator stage, wherein the first portion and the error cancellation network implement the noise transfer function

NTF_{A}(z)=A_{A}z^{-Q}^{_{A}}(1−z⁻¹)^{s}

where A_{A} and Q_{A} are constants and S is equal to Σᵢ₌₁^{L-1} sᵢ, where sᵢ is the order of the EFMᵢ wherein the noise transfer function NTFᵢ(z)=Aᵢz^{-Q}^{ᵢ}(1−z⁻¹)^{s}^{ᵢ} where Aᵢ and Qᵢ are constants with i=1, 2, . . . L−1, and wherein the second portion implements the noise transfer function

$$N T {F}_{B} ( z ) = {A}_{B} {{z}^{- {Q}_{B}} ( 1 - {z}^{- 1} )}^{- S} ( 1 + {\sum }_{i = 1}^{K} {c}_{i} {z}^{- i} )$$

wherein A_{B}, Q_{B} are constants.

In one embodiment, wherein the L Error Feedback Modulator (EFM) stages comprise a first portion and a second portion, wherein the first portion comprises (L−1) error feedback modulator stages and the second portion comprises the Lth error feedback modulator stage, wherein the first portion and the error cancellation network implement the noise transfer function

$$N T {F}_{A} ( z ) = \frac{{( 1 - {z}^{- 1} )}^{S}}{M}$$

where S is equal to Σᵢ₌₁^{L-1} sᵢ, where sᵢ is the order of the EFMᵢ wherein the noise transfer function NTFᵢ(z)=M⁻¹(1−z⁻¹)^{s}^{ᵢ} with i=1, 2, . . . L−1, and wherein the second portion implements the noise transfer function

$${NTF}_{B} ( z ) = \frac{{( 1 - {z}^{- 1} )}^{- S}}{M} ( 1 + {\sum }_{i = 1}^{K} {c}_{i} {z}^{- i} )$$

In one embodiment, L=2.

In one embodiment, the z-domain equation is implemented with an error cancellation network and a nested cascaded structure comprising a plurality of error feedback modulator (EFM) stages connected in a plurality of levels.

In one embodiment, the nested cascaded structure comprises T levels of L error feedback modulator (EFM) stages comprising a first portion and a second portion, wherein the first portion comprises (L−1) error feedback modulator stages of each level and the second portion comprises the Lth error feedback modulator stage of each level, wherein the first portion and the error cancellation network implement the noise transfer function

NTF_{A}(z)=A_{A}z^{-Q}^{_{A}}(1−z⁻¹)^{s}

where A_{A}, Q_{A} are constants and S is equal to Eⱼ₌₁^{L-1} sⱼ, where sⱼ is the order of the EFM_{i,j} wherein the noise transfer function NTF_{i,j}(z)=A_{i,j}z^{-Q}^{_{i,j}}(1−z⁻¹)^{s}^{ⱼ} where A_{i,j} and Q_{i,j} are constants with i=1, 2, . . . T and j=1, 2, . . . L−1, and wherein the second portion implements the noise transfer function

$${NTF}_{B} ( z ) = {A}_{B} {{z}^{- {Q}_{B}} ( 1 - {z}^{- 1} )}^{- S} ( 1 + {\sum }_{i = 1}^{K} {c}_{i} {z}^{- i} )$$

wherein A_{B}, Q_{B} are constants.

In one embodiment, the nested cascaded structure comprises T levels of L error feedback modulator (EFM) stages comprising a first portion and a second portion, wherein the first portion comprises (L−1) error feedback modulator stages of each level and the second portion comprises the Lth error feedback modulator stage of each level, wherein the first portion and the error cancellation network implement the noise transfer function

$${NTF}_{A} = \frac{{( 1 - {z}^{- 1} )}^{S}}{M}$$

where S is equal to Σⱼ₌₁^{L-1} sⱼ, where sⱼ is the order of the EFM_{i,j} wherein the noise transfer function NTF_{i,j}(z)=Mᵢ⁻¹(1−z⁻¹)^{s}^{ⱼ} with i=1, 2, . . . T and j=1, 2, . . . L−1, and wherein the second portion implements the noise transfer function

$${NTF}_{B} ( z ) = \frac{{( 1 - {z}^{- 1} )}^{- S}}{M} ( 1 + {\sum }_{i = 1}^{K} {c}_{i} {z}^{- i} )$$

In one embodiment, a system comprises the disclosed digital delta-sigma modulator for providing a sequence of integers to control a digital-to-analog converter.

In yet another embodiment, a fractional-N PLL device is disclosed comprising:

a phase-locked loop comprising a digitally controlled oscillator, wherein the phase-locked loop generates an output frequency from the digitally controlled oscillator; and the disclosed digital delta-sigma modulator for providing a sequence of integers to control the DCO to produce a desired frequency.

### BRIEF DESCRIPTION OF THE DRAWINGS

The present disclosure will be more clearly understood from the following description of an embodiment thereof, given by way of example only, with reference to the accompanying drawings, in which:

FIG. 1 shows a block diagram of a digital-intensive fractional-N PLL with a DCO;

FIG. 2(a) shows the block diagram of a conventional DCO controller based on a single quantizer digital delta-sigma modulator with shaped additive dither;

FIG. 2(b) shows the linearized model of the conventional DCO controller of FIG. 2(a);

FIG. 3 shows a block diagram of a conventional DCO controller based on a Multi stAge noise SHaping (MASH) digital delta-sigma modulator with shaped additive dither;

FIG. 4(a) shows a block diagram of a conventional Error Feedback Modulator (EFM);

FIG. 4(b) shows an implementation of the conventional Error Feedback Modulator (EFM) of FIG. 4(a);

FIG. 5 shows a block diagram of a conventional DCO controller based on a nested cascaded MASH digital delta-sigma modulator with shaped additive dither;

FIG. 6 shows a block diagram of a conventional additive LSB-dithered MASH 1-1 DCO controller with unfiltered additive dither;

FIG. 7 shows simulated spectra of the unfiltered dither and shaped quantization noise introduced by the DCO controller of FIG. 6;

FIG. 8 shows a simplified phase domain model of the phase noise introduced into the fractional-N frequency synthesizer by the DCO controller of FIG. 6 in the presence of a nonlinear distortion;

FIG. 9 shows simulated power spectral densities of (a) the output y[n] of the DCO controller of FIG. 6 and (b) the output y^{NL}[n] of the DCO controller of FIG. 6 after nonlinear distortion;

FIG. 10 shows a block diagram of a conventional additive LSB-dithered MASH 1-1 DCO controller with bit rotation decoding;

FIG. 11 shows simulated power spectral densities of the output of the DCO controller in FIG. 6 after nonlinear distortion in the case of (a) where bit rotation is applied and (b) where bit rotation is not applied;

FIG. 12 shows a block diagram of an embodiment of a single quantizer inherently spur immune INIS-DDSM DCO controller in accordance with the present disclosure;

FIG. 13 shows a block diagram of an embodiment of an L-stage inherently spur immune INIS-DDSM DCO controller in accordance with the present disclosure, where the first (L−1) stages and the error cancellation network are configured to implement a noise transfer function NTF_{A}(z) and the Lth stage is an error feedback modulator with noise transfer function NTF_{B}(z);

FIG. 14 shows a block diagram of an embodiment of the error feedback modulator in the Lth stage of the L-stage inherently spur immune cascaded INIS-DDSM DCO controller in accordance with the present disclosure;

FIG. 15 shows a block diagram of an embodiment of a two-stage inherently spur immune cascaded INIS-DDSM DCO controller in accordance with the present disclosure, where the first stage is a first-order error feedback modulator with a noise transfer function M⁻¹(1−z⁻¹) and the second stage is an error feedback modulator with noise transfer function M⁻¹(1−z⁻²−z⁻³);

FIG. 16 shows a block diagram of an embodiment of a T-level and L-stage inherently spur immune nested cascaded DCO controller in accordance with the present disclosure, wherein each level comprises (L−1) cascaded stages that together and with the error cancellation network implement a noise transfer function NTF_{A}(z) and the remaining stages, one for each level, are configured to implement a noise transfer function NTF_{B}(z);

FIG. 17 shows a block diagram of an embodiment of a two-level, two-stage inherently spur immune nested cascaded DCO controller in accordance with the present disclosure, where for each level i the first stage is a first-order error feedback modulator with a noise transfer function Mᵢ⁻¹(1−z⁻¹) and the second stage is an error feedback modulator with noise transfer function Mᵢ⁻¹(1+z⁻²−z⁻⁴−z⁻⁵);

FIG. 18 shows the simulated power spectral density of the output of a DCO controller distorted by a memoryless nonlinearity in the case of (a) a MASH 1-1 DCO controller with bit rotation and (b) the cascaded INIS-DDSM with K=4, R=2 shown in FIG. 15;

FIG. 19 shows the simulated power spectral density of the output of a DCO controller distorted by a memoryless nonlinearity in the case of (a) a Successive Requantizer (SR) DCO controller with spur immunity and (b) the nested cascaded INIS-DDSM with K=6, R=3 shown in FIG. 17; and

FIG. 20 shows the simulated power spectral density of the output of a DCO controller distorted by a memoryless nonlinearity in the case of (a) a MASH 1-1 DCO controller without bit rotation, (b) a MASH 1-1 DCO controller with bit rotation and (c) the cascaded INIS-DDSM with K=4, R=2 shown in FIG. 15.

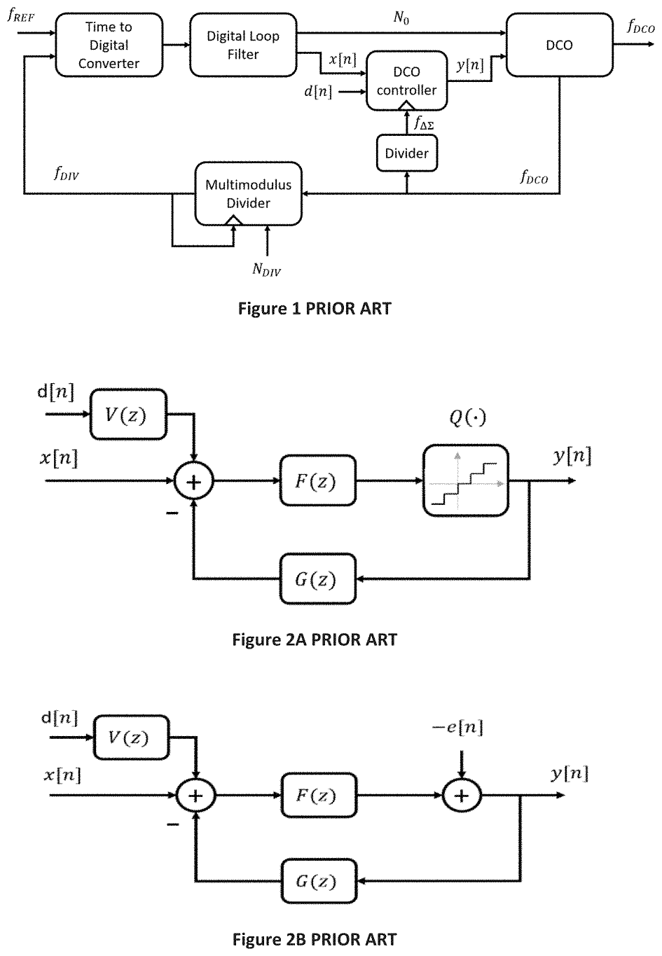

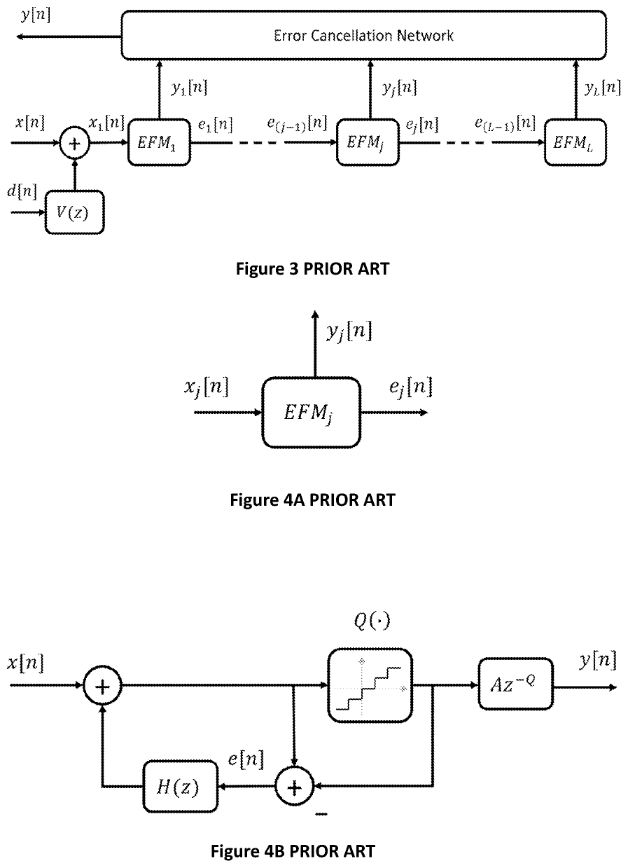

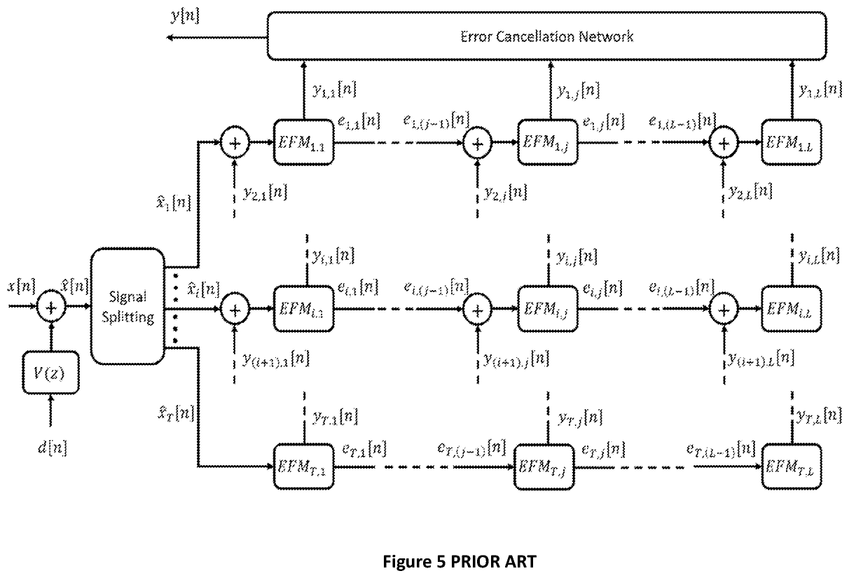

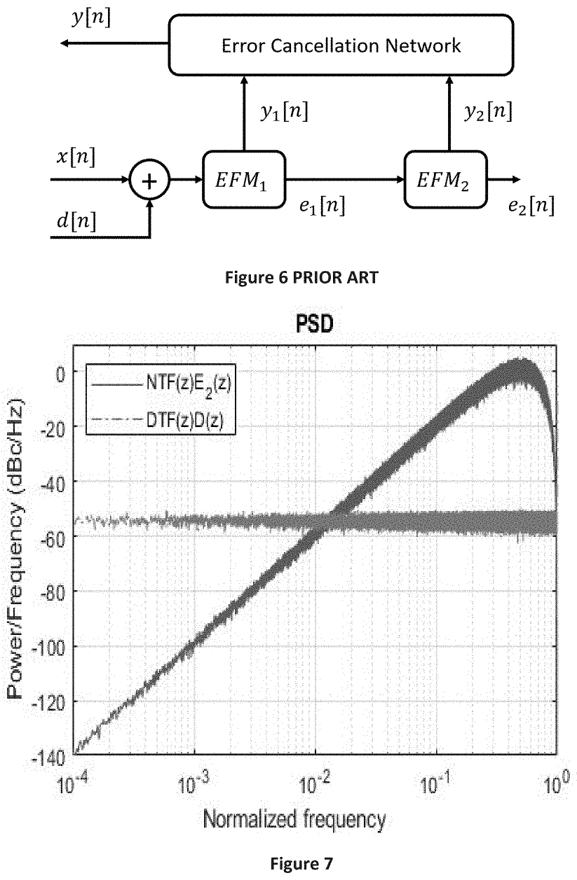

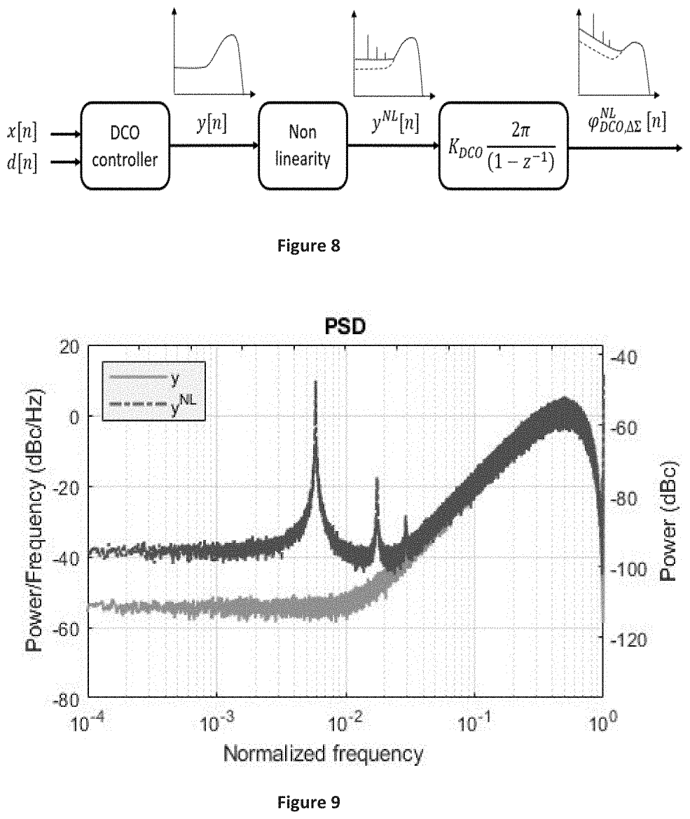

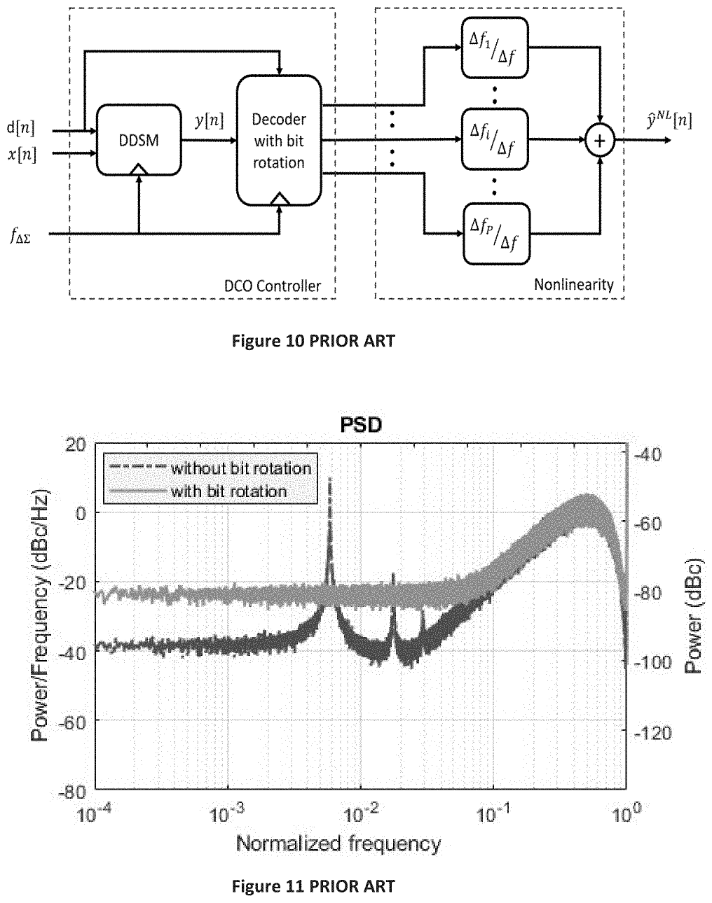

### DETAILED DESCRIPTION

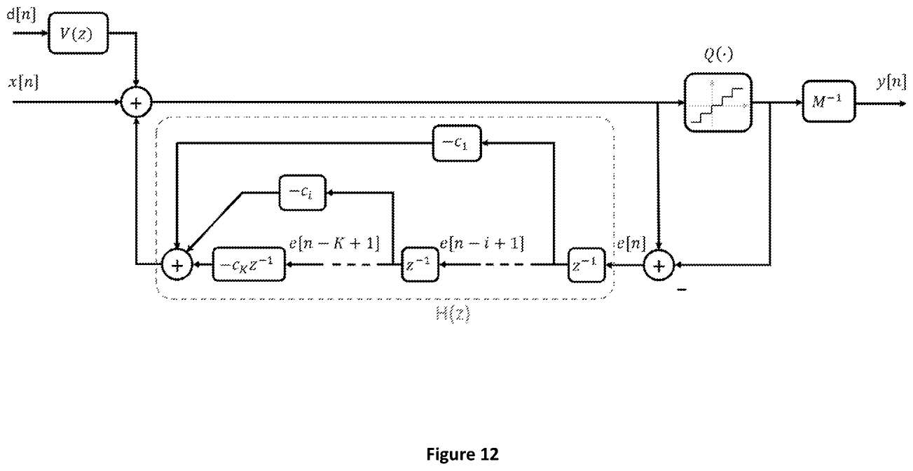

The present disclosure provides a DDSM-based DAC controller that, among other applications, it is suitable for use as a DCO controller with a digital-intensive PLL-based fractional-N frequency synthesizer which provides Immunity from Nonlinearity-Induced Spurs, denoted INIS-DDSM. When used as a DCO controller, this modulator eliminates the spurs that arise due to interaction between the quantization error introduced by the DCO controller and a memoryless nonlinearity in the DCO. Furthermore, it does not exhibit the wandering spur phenomenon. The present disclosure will now be described in conjunction with FIG. 12 onwards.

The digital delta sigma modulator (DDSM) of the disclosure implements the z domain governing equation

Y(z)=STF(z)X(z)+DTF(z)D(z)−NTF(z)E(z),

where Y(z), X(z), D(z) and E(z) are the z transforms of the output, primary input, secondary (dither) input, and quantization error of the DDSM, and wherein STF(z), DTF(z) and NTF(z) are the transfer functions from the primary input, dither input and quantization error to the output and wherein NTF(z) is of the form:

$$NTF ( z ) = {Az}^{- Q} ( 1 + {\sum }_{i = 1}^{K} {c}_{i} {z}^{- i} )$$

where A, Q and K are constants, all the coefficients cᵢ are real valued and c_{K}≠0, and at least one of the zeroes zⱼ of

$$( 1 + {\sum }_{i = 1}^{K} {c}_{i} {z}^{- i} )$$

satisfies zⱼ≠+1 for j=1, 2, . . . , K.

Taking A z^{-Q} to be equal to 1/M, the DCO controller of the disclosure thus implements a Noise Transfer Function

$$NTF ( z ) = \frac{1}{M} ( 1 + {\sum }_{i = 1}^{K} {c}_{i} {z}^{- i} )$$

In one embodiment, the coefficients cᵢ are equal to −1, 0 or 1.

In one embodiment, the coefficients cᵢ are valued such that the noise transfer function can be represented in the form:

$$NTF ( z ) = {Az}^{- Q} ( 1 - {z}^{- 1} ) ( 1 + {\sum }_{i = 1}^{K - 1} {d}_{i} {z}^{- i} )$$

and wherein

$${\sum }_{i = 1}^{K} \vert {c}_{i} \vert \leq - 1 + 2 {\sum }_{i = 1}^{K - 1} \vert {d}_{i} \vert$$

In one embodiment, R number of the coefficients cᵢ are equal to −1, (R−1) number of the coefficients cᵢ are equal to +1 and the other (K−2R+1) number of the coefficients cᵢ are equal to zero, with

$$R \leq \frac{K + 1}{2} .$$

FIG. 12 shows a first embodiment of the present disclosure where the DCO controller comprises a single Error Feedback Modulator (EFM) stage that constitutes a single quantizer digital delta-sigma modulator.

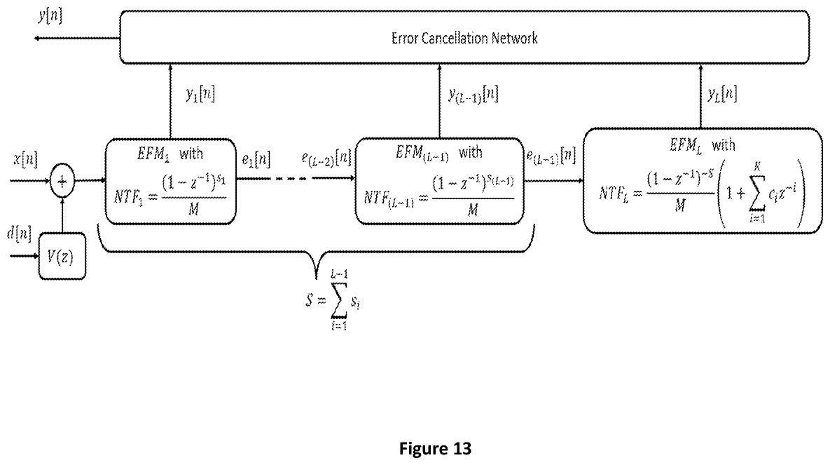

FIG. 13 shows a second embodiment of the present disclosure where the DCO controller comprises an error cancellation network and a cascade of L number single quantizer or Error Feedback Modulator (EFM) stages, wherein the L Error Feedback Modulator (EFM) stages comprise a first portion and a second portion. The first portion comprises (L−1) stages and the second portion comprises the Lth stage. The first portion, together with the error cancellation network, implements a Noise Transfer Function

$${NTF}_{A} ( z ) = \frac{{( 1 - {z}^{- 1} )}^{S}}{M}$$

where S is equal to Σᵢ₌₁^{L-1} sᵢ, where sᵢ is the order of the EFMᵢ wherein the noise transfer function NTFᵢ(z)=M⁻¹(1−z⁻¹)^{s}^{ᵢ} with i=1, 2, . . . (L−1). The second portion, comprising the Lth stage, is configured to implement a Noise Transfer Function

$${NTF}_{B} ( z ) = \frac{{( 1 - {z}^{- 1} )}^{- S}}{M} ( 1 + {\sum }_{i = 1}^{K} {c}_{i} {z}^{- i} ) ,$$

so as to give the overall Noise Transfer Function for the modulator set out previously.

Each of the L stages may be implemented with pipelined combinatorial logic. The outputs of the L stages are combined in the error cancellation network to yield the output y.

DDSMs with constant inputs are known to suffer from limit cycles. Therefore, a binary dither signal, denoted d[n], is added into the signal chain to prevent limit cycle behavior.

In one embodiment, R number of the coefficients cᵢ are equal to −1, (R−1) number of the coefficients cᵢ are equal to +1 and the other (K−2R+1) number of the coefficients cᵢ are equal to zero, with

$$R \leq \frac{K + 1}{2} .$$

For example, with K=6 and R=3, the Noise Transfer Function

NTF(z)=M⁻¹(1−z⁻¹+z⁻²−z⁻³−z⁻⁴+z⁻⁶),

can be implemented in the multistage cascaded structure of FIG. 13 by partitioning factors of the NTF between a number of different stages.

By choosing S=1, the NTF can be realized by a cascade of two stages wherein the NTF of one stage is

NTF(z)=M⁻¹(1−z⁻¹)

and the NTF of the other stage is

NTF(z)=M⁻¹(1+z⁻²−z⁻⁴−z⁻⁵).

By choosing S=2, the NTF can be expressed as

NTF(z)=M⁻¹(1−z⁻¹)²(1+z⁻¹+2z⁻²+2z⁻³+z⁻⁴),

and implemented with a three-stage cascaded structure wherein two identical EFM stages have NTFs of

NTF(z)=M⁻¹(1−z⁻¹)

and the NTF of the third stage is

NTF(z)=M⁻¹(1+z⁻¹+2z⁻²+2z⁻³+z⁻⁴)

Moreover, the same NTF can be implemented with a two-stage cascaded structure wherein one stage has NTF of

NTF(z)=M⁻¹(1−z⁻¹)²

and the second stage has NTF of

NTF(z)=M⁻¹(1+z⁻¹+2z⁻²+2z⁻³+z⁻⁴).

It should be clear that a number of different, but equivalent, partitions of the NTF are possible. The spurious tone immunity derives from the structure of the NTF rather than any particular implementation.

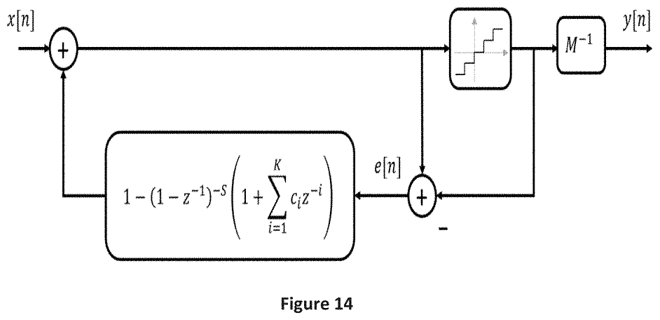

FIG. 14 shows an implementation of the Lth stage of FIG. 13. The output Y(z) is defined by

Y(z)=STF(z)X(z)−NTF_{B}(z)E(z)

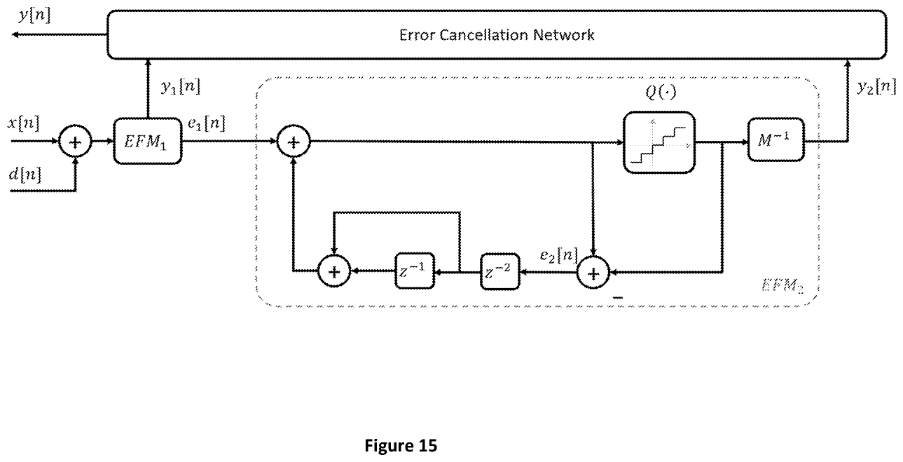

FIG. 15 shows an implementation of the DCO controller in FIG. 13 with L=2 and S=1. Here, the dither signal d[n] has been added at the first stage to implement unfiltered LSB dithering.

In the embodiment of the two-stage cascade in FIG. 15, K=4 and R=2. In particular, the first stage, EFM₁ has a noise transfer function

NTF₁(z)=M⁻¹(1−z⁻¹)

and the second stage, EFM₂, has noise transfer function

NTF₂(z)=M⁻¹(1−z⁻²−z⁻³),

giving an overall Noise Transfer Function for the modulator of

NTF(z)=M⁻¹(1−z⁻¹)(1−z⁻²−z⁻³).

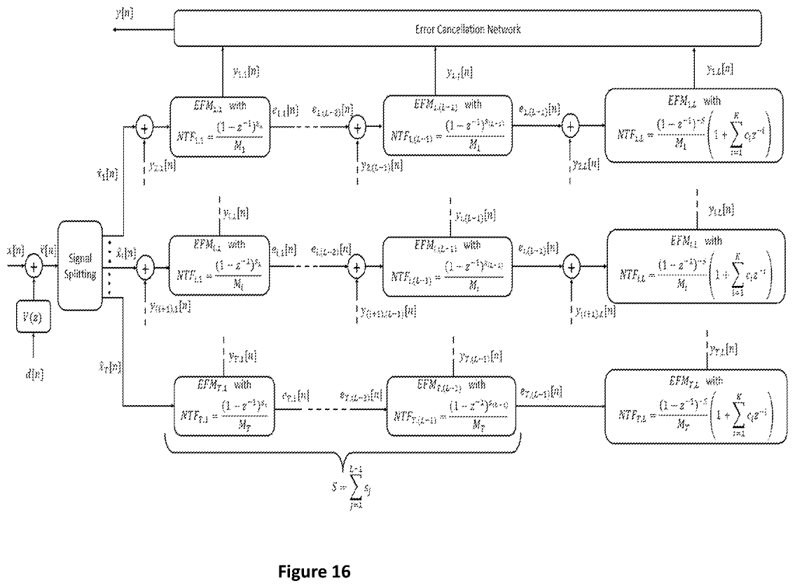

FIG. 16 shows a third embodiment of the present disclosure where the DCO controller comprises an error cancellation network and T levels of L cascaded single quantizer stages comprising a first portion and a second portion. The first portion comprises (L−1) number error feedback modulator stages of each level and the second portion comprises the Lth error feedback modulator stage of each level. The first portion together with the error cancellation network, implement the Noise Transfer Function

$${NTF}_{A} ( z ) = \frac{{( 1 - {z}^{- 1} )}^{S}}{M}$$

where S is equal to Σⱼ₌₁^{L-1} sⱼ, where sⱼ is the order of the EFM_{i,j} wherein the noise transfer function NTF_{i,j}(z)=M⁻¹(1−z⁻¹)^{s}^{ⱼ} with i=1, 2, . . . T and j=1, 2, . . . (L−1). The second portion implements the Noise Transfer Function

$${NTF}_{B} ( z ) = \frac{{( 1 - {z}^{- 1} )}^{- S}}{M} ( 1 + {\sum }_{i = 1}^{K} {c}_{i} {z}^{- i} ) ,$$

so as to give the overall Noise Transfer Function for the modulator set out previously.

The outputs of the L stages of the first cascade are combined in the error cancellation network to yield the output y.

In one embodiment, R number of the coefficients cᵢ are equal to −1, (R−1) number of the coefficients cᵢ are equal to +1 and the other (K−2R+1) number of the coefficients cᵢ are equal to zero, with

$$R \leq \frac{K + 1}{2} .$$

Once again, it should be clear that a number of different, but equivalent, partitions of the NTF over T levels are possible. The spurious tone immunity derives from the structure of the NTF rather than the particular implementation.

Digital delta sigma modulators with constant inputs are known to suffer from cycles. Therefore, a binary dither signal, denoted d[n], is added into the signal chain to prevent cycle behavior.

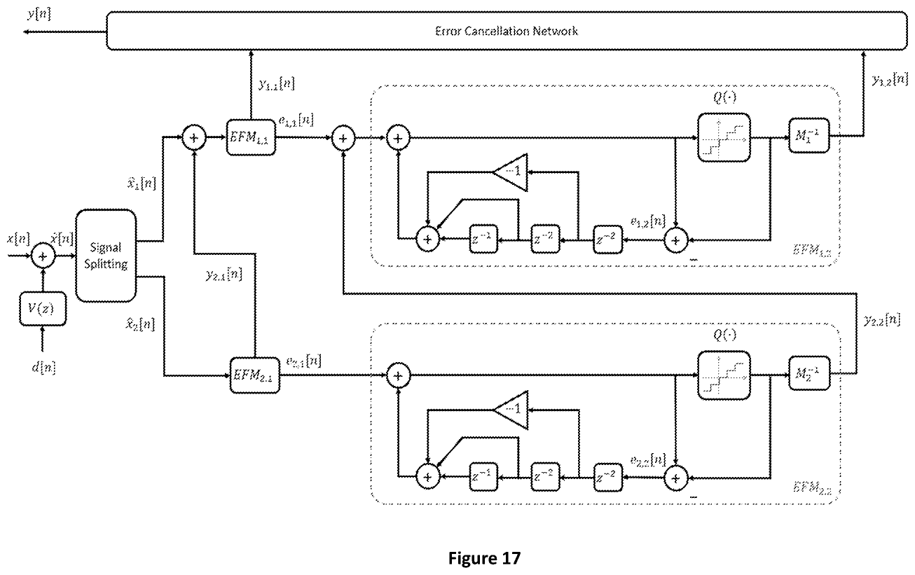

FIG. 17 shows an implementation of the DCO controller in FIG. 16 with T=2, L=2 and S=1. The 8-bit input word x[n] added to the filtered dither is partitioned into two smaller 4-bit words \hat{x}ᵢ[n]. The outputs of the stages of the second cascade are added to the inputs of the stages of the first cascade.

In the embodiment of the two-stage nested cascade in FIG. 17, K=6 and R=3. In particular, the first stage of both levels are EFM1s and have noise transfer functions

NTF_{1,1}(z)=M₁⁻¹(1−z⁻¹)

NTF_{2,1}(z)=M₂⁻¹(1−z⁻¹)

and the remaining stages have noise transfer functions

NTF_{1,2}(z)=M₁⁻¹(1+z⁻²−z⁻⁴−z⁻⁵)

NTF_{2,2}(z)=M₂⁻¹(1+z⁻²−z⁻⁴−z⁻⁵).

giving an overall Noise Transfer Function for the modulator of

NTF(z)=M⁻¹(1−z⁻¹)(1+z⁻²−z⁻⁴−z⁻⁵)

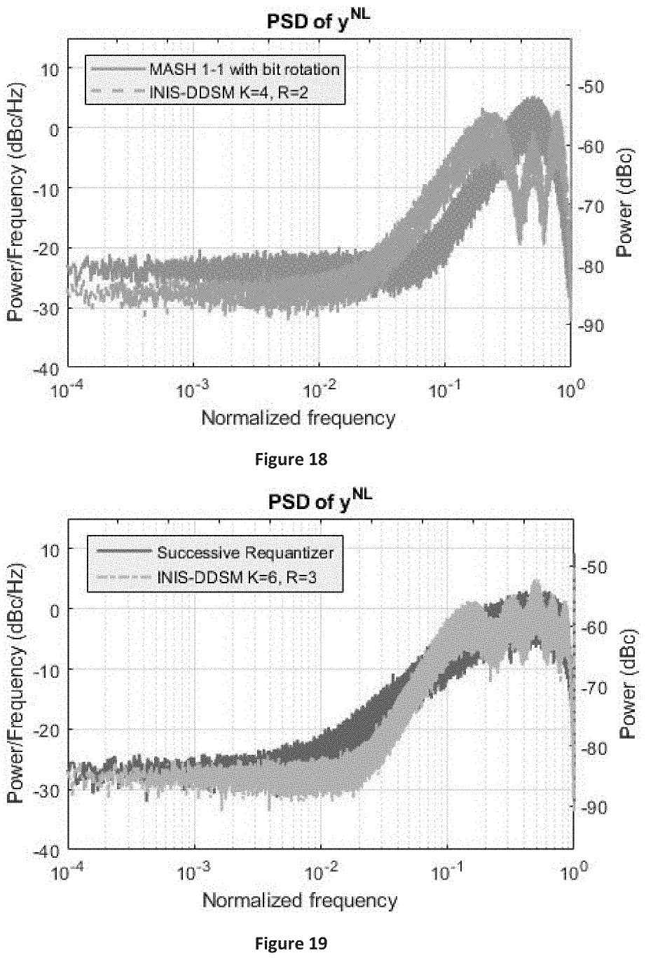

FIG. 18 shows a comparison of the power spectral density of the distorted output of the DCO controller, y^{NL}[n] with two different DCO controllers: (a) the MASH 1-1 with bit rotation and (b) the cascaded INIS-DDSM with K=4, R=2 shown in FIG. 15.

In FIG. 18, x=1 and M=2⁸, and the nonlinearity is the following polynomial function

[symbol]

[x]=0.025+0.933x−0.0875x²+0.0542x³.

The spurs and folded noise caused by interaction between the output y of the DCO controller and the nonlinearity [symbol] [⋅] in the loop can be minimized by choosing NTF_{A}(z) and NTF_{B}(z) as described.

By comparison with the MASH 1-1 with bit rotation DCO controller, it can be seen from FIG. 18 that the use of an INIS-DDSM results in the elimination of spurs and a lower folded noise floor in the spectrogram of y^{NL}[n].

FIG. 19 shows a comparison of the power spectral density of the distorted output of the DCO controller, y^{NL}[n] with two different DCO controllers: (a) the Successive Requantizer and (b) the nested cascaded INIS-DDSM with K=6, R=3 shown in FIG. 17.

In each case, the memoryless nonlinearity is the following polynomial function

N(x)=0.025+0.949x−0.113x²+0.0477x³+0.0256x⁴−0.00896x⁵

Furthermore, x=1 and M=2⁸.

It can be seen from FIG. 19 that the use of the noise transfer function NTF(z)=M⁻¹(1−z⁻¹)(1+z⁻²−z⁻⁴−z⁻⁵) results in the elimination of spurs with a low folded noise floor and a lower PSD of y^{NL}[n] in the range [0.005,0.05] of the normalized frequency.

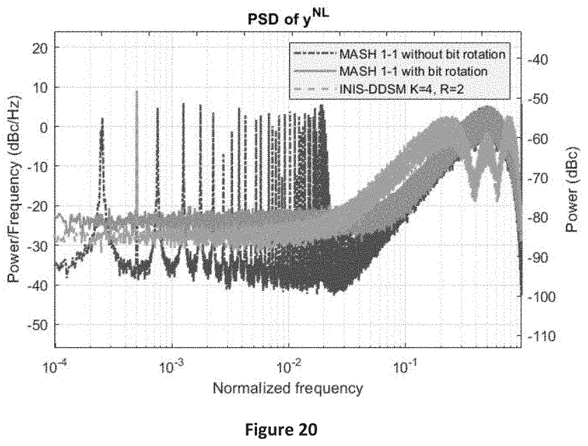

FIG. 20 shows a comparison of the power spectral density of the distorted output of the DCO controller, y^{NL}[n] with three different DCO controllers: (a) the MASH 1-1 without bit rotation, (b) the MASH 1-1 with bit rotation and (c) the cascaded INIS-DDSM with K=4, R=2 shown in FIG. 15.

In FIG. 20, the first input x[n] is a highly oversampled sinusoidal signal,

$$x [ n ] = round ( 10 + 10 sin ( \frac{2 π [ n ]}{2000} ) ) ,$$

where round(⋅) represents the rounding to the nearest integer function, M=2¹⁰, and the nonlinearity is the polynomial function

[symbol]

N[x]=0.025+0.933x−0.0875x²+0.0542x³.

The case of the MASH 1-1 without bit rotation exhibits the lowest folded noise but it also shows many spurious tones. The latter can be mitigated by using bit rotation, at the cost of an elevated noise floor.

The spurs and folded noise caused by interaction between the output y of the DCO controller and the nonlinearity [symbol] [-] in the loop can be minimized by choosing NTF_{A}(z) and NTF_{B}(z) as described.

By comparison with the MASH 1-1 DCO controller with bit rotation, it can be seen from FIG. 20 that the use of an INIS-DDSM results in the elimination of spurs and a lower folded noise floor in the spectrogram of y^{NL}[n].

When used as a DCO controller, the INIS DDSM can be appreciated for improving the noise performance in terms of mitigation of spurs and reduction of folded noise in cases of both constant and slowly time-varying inputs

When incorporated in a fractional-N frequency synthesizer, the DDSM-based DCO controller has an output y[n] with a range that has a spread P, where P represents the number of capacitance steps driven by y[n]. In the presence of mismatch between the capacitances of the P capacitors, the signal y[n] encounters a memoryless nonlinearity that can be always expressed as a polynomial function with order P.

That being said, the INIS DCO controller of the present disclosure with noise transfer function NTF(z)=M⁻¹(1+Σᵢ₌₁^{K} cᵢz⁻ⁱ) which satisfies the conditions described above and with a given R does not exhibit spurs if

$$R \geq \frac{P + 1}{2} .$$

Furthermore, the INIS-DDSM of the present disclosure is characterized by having an output y[n] that has a spread P=(2R−1). It follows that

$$R = \frac{P + 1}{2}$$

and, therefore, the DCO controller is inherently immune to any memoryless nonlinearity that is faced by y[n].

Accordingly, the use of a DDSM based DCO controller having the above described noise transfer function results in the generation of a signal that is characterised by an improved spur immunity performance when distorted by static polynomial nonlinearities. Thus, it will be appreciated that the DCO controller of the present disclosure, when used with a fractional-N frequency synthesizer, provides a signal that is immune from spurs and less prone to produce folded noise than a frequency synthesizer which uses a conventional dithered digital delta-sigma modulator. Through the minimization of nonlinearity-induced folded noise and the mitigation of spurs, it enables the frequency synthesizer to generate cleaner carriers for a range of applications including communications, radar and instrumentation.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The present disclosure is not limited to the embodiments hereinbefore described but may be varied in both construction and detail.

1. A digital delta-sigma modulator (DDSM) with an input signal x[n], an output signal y[n], a quantization error signal e [n] and a dither signal d[n], having an equation described in the z-domain by
Y(z)=STF(z)X(z)+DTF(z)D(z)−NTF(z)E(z)
wherein Y(z), X(z), D(z) and E(z) are z-transforms of the output signal, the input signal, the dither signal, and the quantization error signal, and wherein STF(z), DTF(z) and NTF(z) correspond to a transfer function of the input signal, a transfer function of the dither signal, and a transfer function of the quantization error signal, and wherein the transfer function of the quantization error signal is of the form:
$$NTF ( z ) = {Az}^{- Q} ( 1 + {\sum }_{i = 1}^{K} {c}_{i} {z}^{- i} ) ,$$
where A, Q and K are constants, coefficients cᵢ are real valued and c_{K}≠0 and wherein at least one of the zeroes zⱼ of
$$( 1 + {\sum }_{i = 1}^{K} {c}_{i} {z}^{- i} )$$
satisfies zⱼ≠+1 for j=1, 2, . . . , K.

2. The digital delta-sigma modulator of claim 1, wherein the coefficients cᵢ are equal to −1,0 or 1.

3. The digital delta-sigma modulator of claim 1, wherein R coefficients cᵢ are equal to −1, (R−1) coefficients cᵢ are equal to +1 and the other (K−2R+1) coefficients cᵢ are equal to zero, with
$$R \leq \frac{K + 1}{2} .$$

4. The digital delta-sigma modulator of claim 1 wherein the coefficients cᵢ are valued such that the noise transfer function can be represented in the form:
$$NTF ( z ) = {Az}^{- Q} ( 1 - {z}^{- 1} ) ( 1 + {\sum }_{i = 1}^{K - 1} {d}_{i} {z}^{- i} )$$
and wherein
$${\sum }_{i = 1}^{K} \vert {c}_{i} \vert \leq - 1 + 2 {\sum }_{i = 1}^{K - 1} \vert {d}_{i} \vert$$

5. The digital delta-sigma modulator of claim 1 wherein the z-domain equation is implemented with a multi-bit single-quantizer DDSM architecture.

6. The digital delta-sigma modulator of claim 1, wherein the z-domain equation is implemented with a multistage noise shaping cascaded DDSM architecture comprising an error cancellation network and L≥2 error feedback modulator (EFM) stages, wherein an error output eⱼ of stage j is applied as an input to stage (j+1) and wherein outputs yⱼ of the L stages are combined in the error cancellation network to provide the output y.

7. The digital delta-sigma modulator of claim 6, wherein the L Error Feedback Modulator (EFM) stages comprise a first portion and a second portion, wherein the first portion comprises (L−1) error feedback modulator stages and the second portion comprises the Lth error feedback modulator stage, wherein the first portion and the error cancellation network implement the noise transfer function
NTF_{A}(z)=A_{A}z^{-Q}^{_{A}}(1−z⁻¹)^{s}
wherein A_{A}, Q_{A} are constants and S is equal to Σᵢ₌₁^{L-1} sᵢ, where sᵢ is the order of the EFMᵢ wherein the noise transfer function NTFᵢ(z)=Aᵢz^{-Q}^{ᵢ}(1−z⁻¹)^{s}^{ᵢ} where Aᵢ and Qᵢ are constants with i=1, 2, . . . (L−1), and wherein the second portion implements the noise transfer function
$$N T {F}_{B} ( z ) = {A}_{B} {{z}^{- {Q}_{B}} ( 1 - {z}^{- 1} )}^{- S} ( 1 + {\sum }_{i = 1}^{K} {c}_{i} {z}^{- i} )$$
wherein A_{B}, Q_{B} are constants.

8. The digital delta-sigma modulator of claim 6, wherein the L Error Feedback Modulator (EFM) stages comprise a first portion and a second portion, wherein the first portion comprises (L−1) error feedback modulator stages and the second portion comprises the Lth error feedback modulator stage, wherein the first portion and the error cancellation network implement the noise transfer function
$$N T {F}_{A} ( z ) = \frac{{( 1 - {z}^{- 1} )}^{S}}{M}$$
wherein S is equal to Σᵢ₌₁^{L-1} sᵢ, where sᵢ is the order of the EFMᵢ wherein the noise transfer function NTFᵢ(z)=M⁻¹(1−z⁻¹)^{s}^{ᵢ} with i=1, 2, . . . (L−1), and wherein the second portion implements the noise transfer function
$$N T {F}_{B} ( z ) = \frac{{( 1 - {z}^{- 1} )}^{- S}}{M} ( 1 + {\sum }_{i = 1}^{K} {c}_{i} {z}^{- i} )$$

9. The digital delta-sigma modulator of claim 6, wherein L=2.

10. The digital delta-sigma modulator of claim 1, wherein the z-domain equation is implemented with an error cancellation network and a nested cascaded structure comprising a plurality of error feedback modulator (EFM) stages connected in a plurality of levels.

11. The digital delta-sigma modulator of claim 10, wherein the nested cascaded structure comprises T levels of L error feedback modulator (EFM) stages comprising a first portion and a second portion, wherein the first portion comprises (L−1) error feedback modulator stages of each level and the second portion comprises the Lth error feedback modulator stage of each level, wherein the first portion and the error cancellation network implement the noise transfer function
NTF_{A}(z)=A_{A}z^{-Q}^{_{A}}(1−z⁻¹)^{s}
where A_{A}, Q_{A} are constants and S is equal to Eⱼ₌₁^{L-1} sⱼ, where sⱼ is the order of the EFM_{i,j} wherein the noise transfer function NTF_{i,j}(z)=A_{i,j}z^{-Q}^{_{i,j}}(1−z⁻¹)^{s}^{ⱼ} where A_{i,j} and Q_{i,j} are constants with i=1, 2, . . . T and j=1, 2, . . . (L−1), and wherein the second portion implements the noise transfer function
$$N T {F}_{B} ( z ) = {A}_{B} {{z}^{- {Q}_{B}} ( 1 - {z}^{- 1} )}^{- S} ( 1 + {\sum }_{i = 1}^{K} {c}_{i} {z}^{- i} )$$
wherein A_{B}, Q_{B} are constants.

12. The digital delta-sigma modulator of claim 10, wherein the nested cascaded structure comprises T levels of L error feedback modulators (EFM) stages comprising a first portion and a second portion, wherein the first portion comprises (L−1) error feedback modulator stages of each level and the second portion comprises the Lth error feedback modulator stage of each level, wherein the first portion and the error cancellation network implement the noise transfer function
$$N T {F}_{A} ( z ) = \frac{{( 1 - {z}^{- 1} )}^{S}}{M}$$
where S is equal to Σⱼ₌₁^{L-1} sⱼ, where sⱼ is the order of the EFM_{i,j} wherein the noise transfer function NTF_{i,j}(z)=Mᵢ⁻¹(1−z⁻¹)^{s}^{ⱼ} with i=1, 2, . . . T and j=1, 2, . . . (L−1), and wherein the second portion implements the noise transfer function
$$N T {F}_{B} ( z ) = \frac{{( 1 - {z}^{- 1} )}^{- S}}{M} ( 1 + {\sum }_{i = 1}^{K} {c}_{i} {z}^{- i} )$$

13. A system comprising a digital-to-analog converter and the digital delta-sigma modulator of claim 1 for providing a sequence of integers to control a DCO or DAC.

14. A fractional-N PLL device, comprising:
a phase-locked loop comprising a digitally controlled oscillator, wherein the phase-locked loop generates an output frequency from the digitally controlled oscillator; and
the digital delta-sigma modulator of claim 1 for providing a sequence of integers to control the DCO to produce a desired frequency.
